(19) United States
(12) Patent Application Publication
(10) Pub. No.: US 2014/0014991 A1
(43) Pub. Date: Jan. 16, 2014

(54) Light-Emitting Element with Window Layers Sandwiching Distributed Bragg Reflector

(71) Applicant: EPISTAR CORPORATION, Hsinchu (TW)

(72) Inventors: Po-Shun Chiu, Tainan (TW); De-Shan Kuo, Tainan (TW); Chun-Hsiang Tu, Tainan (TW); Chun-Teng Ko, Tainan (TW)

(21) Appl. No.: 13/918,150

(22) Filed: Jun. 14, 2013

Related U.S. Application Data
(60) Provisional application No. 61/671,502, filed on Jul. 13, 2012.

(51) Int. Cl. H01L 33/60

(52) U.S. Cl. CPC H01L 33/60
USPC 257/98

(57) ABSTRACT

A light-emitting element includes a substrate; a light-emitting stacked layer on the substrate; a first window layer under the substrate; and a DBR under the first window layer; wherein the first window layer has a width substantially equal to that of the substrate in a cross-sectional view.

### RELATED APPLICATION

This application claims the benefit of provisional application No. 61/671,502 filed on Jul. 13, 2012; the contents of which are incorporated herein by reference in its entirety.

### BACKGROUND

1. Technical Field

The present disclosure relates to a light-emitting element, and more particularly, to a light-emitting element having window layers sandwiching a Distributed Bragg Reflector (DBR).

2. Description of the Related Art

Light-emitting Diode (LED) is a solid state semiconductor element having a p-n junction formed between a p-type semiconductor layer and an n-type semiconductor layer. When imposing a certain level of forward voltage to an LED, holes from the p-type semiconductor layer can radiativeiy recombine with electrons from the n-type semiconductor layer to release light. The region where the recombination occurs is generally called a light-emitting region or an active layer.

The primary features of an LED include its smaller size, higher reliability, higher efficiency, longer lifetime, and faster response time. The LED has been applied widely to optical display devices, traffic signals, data storage devices, communication devices, illumination devices, and medical apparatuses. With the emersion of the white-light LEDs, the conventional illumination sources, such as fluorescent and incandescent lamps, are gradually replaced by LEDs.

A conventional light-emitting element 2 includes a substrate 20; a light-emitting structure 22 on the substrate 20; a first electrode 24 and a second electrode 26 on the light-emitting structure 22; and a DBR 28 under the substrate 20. The DBR 28 includes sublayers 282 and 284 which are alternately stacked with each other, as shown in FIG. 2. The light from the light-emitting structure 22 can be reflected by the DBR 28. Some light, however, may be trapped within the sublayers 282 and 284 of the DBR 28 and eventually converted to heat after several total internal reflections. Moreover, the lateral surfaces of the substrate 20 are too small to extract the light reflected by the DBR 28. Thus, the light extraction efficiency of the conventional light-emitting element 2 is reduced.

### SUMMARY OF THE DISCLOSURE

A light-emitting element includes a substrate; a light-emitting stacked layer on the substrate; a first window layer under the substrate; and a DBR under the first window layer; wherein the first window layer has a width substantially equal to that of the substrate in a cross-sectional view

### BRIEF DESCRIPTION OF THE DRAWINGS

The accompanying drawings are included to provide easy understanding of the application, and are incorporated herein and constitute a part of this specification. The drawings illustrate embodiments of the application and, together with the description, serve to illustrate the principles of the application.

FIG. 1 illustrates a cross-sectional view of a light-emitting element in accordance with an embodiment of the present application.

FIG. 2 illustrates a cross-sectional view of a conventional light-emitting element,

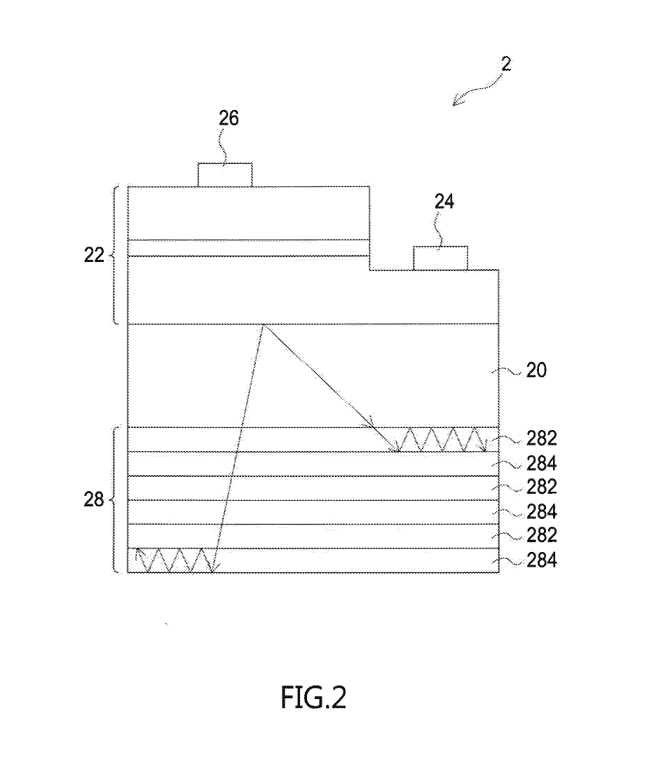

FIG. 3 illustrates an explosive diagram of a bulb in accordance with another embodiment of the present application.

### DETAILED DESCRIPTION OF THE EMBODIMENTS

To better and concisely explain the disclosure, the same name or the same reference number given or appeared in different paragraphs or figures along the specification should has the same or equivalent meanings while it is once defined anywhere of the disclosure.

The following shows the description of the embodiments of the present disclosure accompanying with the drawings.

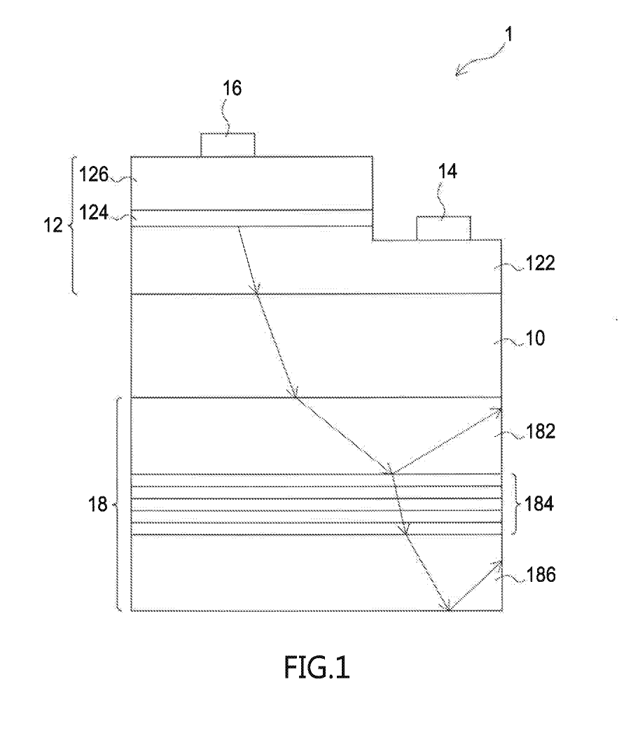

FIG. 1 illustrates a light-emitting element 1 including a substrate 10; a light-emitting stacked layer 12 formed on the substrate 10; and a light extraction structure 18 formed under the substrate 10. The light-emitting stacked layer 12 includes a first semiconductor layer 122; a second semiconductor layer 126; and an active layer 124 between the first semiconductor layer 122 and the second semiconductor layer 126. Moreover, a first electrode 14 is formed on the first semiconductor layer 122. A second electrode 16 is formed on the second semiconductor layer 126.

The light extraction structure 18 includes a first window layer 182 under the substrate 10, a second window layer 186 under the first window layer 182, and a DBR 184 between the second window layer 186 and the first window layer 182, wherein the DBR 184 includes a plurality of sublayers. At least one of the first window layer 182 and the second window layer 186 is for improving light extraction efficiency, and has a width substantially equal to that of the substrate 10 in a cross-sectional view, as shown in FIG. 1. However, the first window layer 182 may also has a width greater or smaller than that of the second window layer 186 in a cross-sectional view in order to adjust the light field of the light-emitting element 1 to meet the product application in another embodiment. The DBR 184 can reflect light generated from the light-emitting stacked layer 12. The DBR 184 typically has several pairs of materials having different refractive indices. The difference of the refractive indices is at least 0.5, preferably at least 1.

TABLE 1

| | Power (mW) |
|---|---|
| Example 1 | 111.66 |
| Example 2 | 112.78 |

The first window layer 182, the second window layer 186, or both cannot cover or physically contact with the lateral surfaces of the light-emitting stacked layer 12 so the heat generated by the light-emitting stacked layer 12 can be dissipated more easily. Each of the first window layer 182 and the second window layer 186 has a thickness about between 300 nm and 1000 nm, preferably between 450 nm and 550 nm for improving the light extraction efficiency of the light-emitting element 1. Table 1 shows experimental results of Examples 1 and 2. Referring to Table 1, Example 1 represents that a thickness of the second window layer 186 is about 70 nm and Example 2 represents that a thickness of the second window layer 186 is about 500 nm. Example 2 presents larger power than Example 1. It indicates that Example 2 has higher light extraction efficiency than Example 1. Each sublayer of the DBR 184 has a thickness about between 30 nm and 80 nm, preferably about between 40 nm and 60 nm. The number of the pairs of the DBR 184 is between 5 and 50, preferably between 5 and 15. The DBR 184 has a total thickness about between 300 nm and 8000 nm, preferably about between 500 nm and 1500 nm. A ratio of the thickness of the window layer 182 or 186 to the total thickness of the DBR 184 is about between 0.03 and 3.33, preferably about between 0.3 and 1.1 for improving the light extraction efficiency of the light-emitting element 1. The first window layer 182, the second window layer 186, or both are thick enough so the light trapped within the DBR 184 or the light-emitting stacked layers 12 can be extracted from the lateral surfaces of the first window layer 18, the second window layer 186, or both. The material of the window layer is transparent to light generated from the light-emitting stacked layer 12, and constructed of conductive material(s) or insulating material(s). The conductive material can be ITO, NO, SnO, CTO, ATO, ZnO, MgO, AlGaAs, GaN, GaP, AZO, ZTO, GZO, and IZO. The insulating material can be Su8, benzocyclobutene (BCB), perfluorocyclobutane (PFCB), epoxy, acrylic resin, cyclic olefin copolymers (COC), polymethyl methacrylate (PMMA), polyethylene terephthalate (PET), polyimide (PI), polycarbonate (PC), polyetherimide, fluorocarbon polymer, glass, Ta₂O₅, Al₂O₃, SiO₂, TiO₂, SiNₓ, spin-on-glass (SOG), and tetraethoxysilane (TEOS). The material of each of the plurality of sublayers can be the same as that of the window layer.

The first window layer 182, the second window layer 186, or both function as parts of the DBR structure in another embodiment. Each sublayer of the DBR structure has a thickness following an equation of d=m(λ/4n), wherein d represents the thickness of the sublayer, λ represents the wavelength of the light reflected by DBR structure, n represents the refractive index of the sublayer, and in represents any positive integer. When the wavelength of the light reflected by DBR structure is about 460 nm, for example, and the refractive indices of the first sublayer 182 and the second sublayer 186 are about 1.5, in is not smaller than 3, preferably 3 to 7, to increase the light extraction efficiency,

The substrate 10 can be used to grow and/or support the light-emitting stacked layer 12 thereon. The material of the substrate 10 is transparent to light from the light-emitting stacked layer 12, and can include insulating material, conductive material, or both. The insulating material can be sapphire, diamond, glass, quartz, acryl, and AlN. The conductive material can be SiC, IP, GaAs, Ge, GaP, GaAsP, ZnSe, ZnO, InP, LiGaO2, and LiAlO2.

The light-emitting stacked layer 12 can be directly grown on the substrate 10, or attached to the substrate 10 by a bonding layer (not shown). The light-emitting stacked layer 12 can be composed of semiconductor material(s) having at least one element selected from a group consisting of Ga, Al, In, As, P, N, Zn, Cd, and Se. The polarities of the first semiconductor layer 122 and the second semiconductor layer 126 are different from each other. The first semiconductor layer 122 and the second semiconductor layer 126 can generate electrons and holes. The active layer 124 can generate light with one or more colors. The light generated form the light-emitting stacked layer 12 can be visible or non-visible. A structure of the active layer 124 can include single heterostructure (SH), double heterostructure (DH), double-side double heterostructure (DDH), or multi-quantum well (MQW).

The first electrode 14, the second electrode 16, or both are used to undergo an external voltage. The first electrode 14, the second electrode 16, or both can be made of a transparent conductive a ial, a metallic material, or both. The transparent conductive material includes but not limited to ITO, InO, SnO, CTO, ATO, AZO, ZTO, ZnO, IZO, DLC. GZO, and any combination thereof. The metal material includes but not limited to Cu, Al, In, Sn, Au, Pt, Zn, Ag, Ti, Ni, Pb, Pd, Ge, Ni, Cr, Cd, Co, Mn, Sb, Bi, Ga, W, Be, Ag—Ti, Cu—Sn, Cu—Zn, Cu—Cd, Sn—Pb—Sb, Sn—Pb—Zn, Ni—Sn, Ni—Co, Ag—Cu, Ge—Au, Au alloy, and any combination thereof.

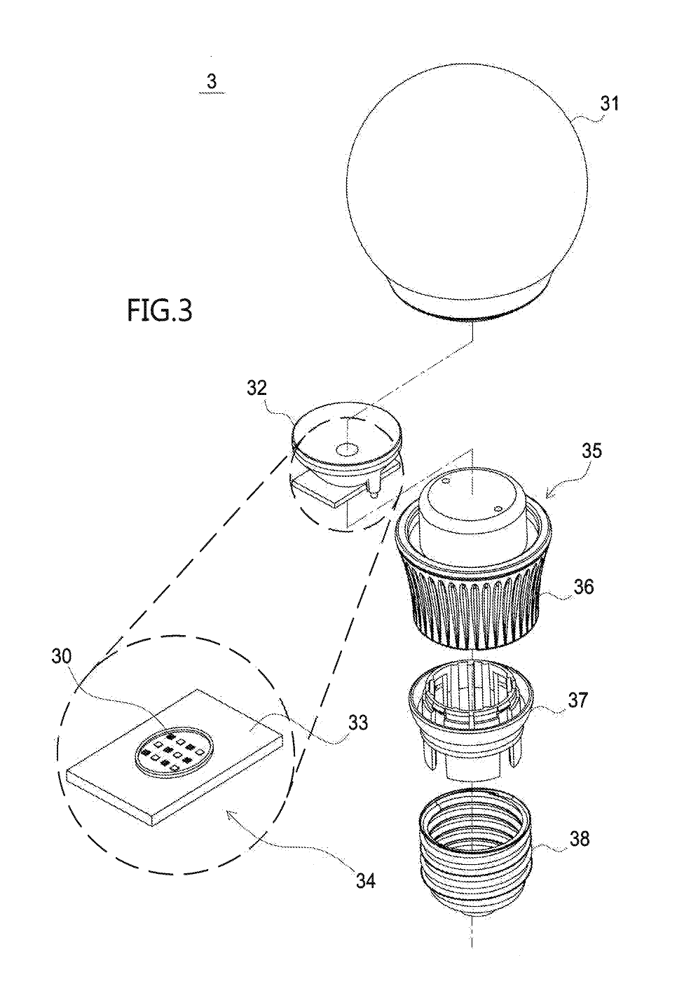

FIG. 3 shows an explosive diagram of a bulb in accordance with another application of the present application. The bulb 3 includes a cover 31, a lens 32, a lighting module 34, a lamp holder 35, a heat sink 36, a connecting part 37, and an electrical connector 38. The lighting module 34 includes a carrier 33 and a plurality of light-emitting elements 30 of any one of the above mentioned embodiments on the carrier 33.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

What is claimed is:

1. A light-emitting element, comprising:
a substrate;
a light-emitting stacked layer on the substrate;
a first window layer under the substrate; and
a DBR under the first window layer,
wherein the first window layer has a width substantially equal to that of the substrate in a cross-sectional view.

2. The light-emitting element of claim 1, wherein a material of the first window layer is conductive material or insulating material.

3. The light-emitting element of claim 2, wherein the conductive material is selected from a group consisting of ITO, InO, SnO, CTO, ATO, ZnO, MgO, AlGaAs, GaN, GaP, AZO, ZTO, GZO, and IZO.

4. The light-emitting element of claim 2, wherein the insulating material is selected from a group consisting of Su8, benzocyclobutene (BCB), perfluorocyclobutane (PFCB), epoxy, acrylic resin, cyclic olefin copolymers (COC), polymethyl methacrylate (PMMA), polyethylene terephthalate (PET), polyimide (PI), polycarbonate (PC), polyetherimide, fluorocarbon polymer, glass, Ta₂O₅, Al₂O₃, SiO₂, TiO₂, SiNₓ, spin-on-glass (SOG), and tetraethoxysilane (TEOS).

5. The light-emitting element of claim 1, wherein a thickness of the first window layer is between 450 nm and 550 nm.

6. The light-emitting element of claim 1, wherein a ratio of thickness of the first window layer to the DBR is between 0.3 and 1.1.

7. The light-emitting element of claim 1, wherein a thickness of the first window layer is represented by an equation of d=m(λ/4n), wherein d represents the thickness, represents the wavelength of the light generated from the light-emitting stacked layer, n represents the refractive index of the first window layer, and m is 3 to 7.

8. The light-emitting element of claim 1, wherein the DBR comprises a pair of materials having different refractive indices, wherein the difference of the refractive indices is at least 0.5.

9. The light-emitting element of claim 1, further comprising a second window layer under the DBR.

10. The light-emitting element of claim 9, wherein a material of the second window layer is conductive material or insulating material.

11. The light-emitting element of claim 10, wherein the conductive material is selected from a group consisting of ITO, NO, SnO, CTO, ATO, ZnO, MgO, AIGaAs, GaN, GaP, AZO, ZTO, GZO, and IZO.

12. The light-emitting element of claim 10, wherein the insulating material is selected from a group consisting of Su8, benzocyclobutene (BCB), perfluorocyclobutane (PFCB), epoxy, acrylic resin, cyclic olefin copolymers (COC), polymethyl methacrylate (PMMA), polyethylene terephthalate (PET), polyimide (PI), polycarbonate (PC), polyetherimide, fluorocarbon polymer, glass, Ta₂O₅, Al₂O₃, SiO₂, TiO₂, SiNₓ, spin-on-glass (SOG), and tetraethoxysilane (TEOS).

13. The light-emitting element of claim 9, wherein thickness of the second window layer is between 450 nm and 550 nm.

14. The light-emitting element of claim 9, wherein a ratio of thickness of the second window layer to the DBR is between 0.3 and 1.1.

15. The light-emitting element of claim 9, wherein a thickness of the second window layer is represented by an equation of d=m(λ/4n), wherein d represents the thickness, λ represents the wavelength of the light generated from the light-emitting stacked layer, n represents the refractive index of the first window layer, and m is 3 to 7.
